(19) United States
(12) Patent Application Publication
(10) Pub. No.: US 2013/0105207 A1
(43) Pub. Date: May 2, 2013

(54) TRANSPARENT CONDUCTIVE FILM

(71) Applicant: NITTO DENKO CORPORATION, Osaka (JP)

(72) Inventors: Mizue Yamasaki, Ibaraki-shi (JP); Tomotake Nashiki, Ibaraki-shi (JP); Kuniaki Ishibashi, Ibaraki-shi (JP)

(73) Assignee: NITTO DENKO CORPORATION, Osaka (JP)

(21) Appl. No.: 13/660,244

(22) Filed: Oct. 25, 2012

(30) Foreign Application Priority Data
Oct. 28, 2011 (JP) 2011-237081

(51) Int. Cl. H05K 1/02; H05K 1/09; H05K 1/03

(52) U.S. Cl. 174/257; 174/268; 174/258

(57) ABSTRACT

There is provided a transparent conductive film which comprises: a first transparent film; a plurality of transparent electrode patterns; a transparent adhesive layer; and a second transparent film. The first transparent film and the second transparent film are laminated with the transparent adhesive layer interposed therebetween. The first transparent film has a thickness of 15 μm to 55 μm. The second transparent film has a thickness 1.5 times to 6 times as great as that of the first transparent film. The transparent adhesive layer is a curing adhesive layer having a thickness of not less than 0.01 μm and less than 10 μm.

### BACKGROUND OF THE INVENTION

1. Field of the Invention

The present invention relates to a transparent conductive film used for a capacitance-type touch panel or the like.

2. Description of Related Art

A transparent conductive film in which a plurality of transparent electrode patterns are formed on a laminate formed by bonding two films is known (Japanese Unexamined Patent Application Publication No. JP 2009-76432 A). The two films are bonded to each other with a pressure-sensitive adhesive layer having a thickness of about 20 μm interposed therebetween. In the case where such a transparent conductive film is used for a resistive touch panel, the transparent conductive film has superior pen input durability and surface pressure durability because the pressure-sensitive adhesive layer has a cushion characteristic. The plurality of transparent electrode patterns are generally formed by etching. In a conventional transparent conductive film, there is a difference in shrinkage ratio of the film between a portion with transparent electrode patterns and a portion without transparent electrode patterns when heated in the etching process. Accordingly, waviness tends to occur on the transparent conductive film. It is preferable to have less waviness.

### SUMMARY OF THE INVENTION

It is an object of the present invention to provide a transparent conductive film having less waviness than ever before.

The summary of the present invention is as follows:

In a first preferred aspect, a transparent conductive film according to the present invention comprises: a first film; a plurality of transparent electrode patterns; a transparent adhesive layer; and a second film. The first and second films are transparent. The plurality of transparent electrode patterns are formed on one surface of the first film. The transparent adhesive layer is laminated on the other surface (the surface without transparent electrode patterns) of the first film. The second film is laminated on a surface of the transparent adhesive layer that is on the opposite side of the first film. The transparent adhesive layer is a curing adhesive layer. The second film has a thickness 1.5 times to 6 times as great as the first film has.

In a second preferred aspect of the transparent conductive film according to the present invention, the first film has a thickness of 15 μm to 55 μm.

In a third preferred aspect of the transparent conductive film according to the present invention, the transparent adhesive layer has a thickness of not less than 0.01 μm and less than 10 μm.

In a fourth preferred aspect of the transparent conductive film according to the present invention, a curing adhesive for forming the curing adhesive layer is an ultraviolet curing adhesive or an electron beam curing adhesive.

In a fifth preferred aspect of the transparent conductive film according to the present invention, the first film and the second film respectively have a dielectric constant of 2.0 to 3.5 at 1 MHz.

In a sixth preferred aspect of the transparent conductive film according to the present invention, each material for forming the first film and the second film is any one of polyethylene terephthalate, polycycloolefin or polycarbonate.

In a seventh preferred aspect of the transparent conductive film according to the present invention, a material for forming the plurality of transparent electrode patterns is any one of indium tin oxide (ITO), indium zinc oxide or indium oxide-zinc composite oxide.

### ADVANTAGES OF THE INVENTION

According to the present invention, it is possible to obtain a transparent conductive film having less waviness than ever before. Further, a capacitance-type touch panel using the transparent conductive film of the present invention is more superior in touch sensitivity than a capacitance-type touch panel using a conventional transparent conductive film.

### BRIEF DESCRIPTION OF THE DRAWING

FIG. 1 shows a plan view and a schematic cross-sectional view of a transparent conductive film of the present invention.

### DESCRIPTION OF THE PREFERRED EMBODIMENTS

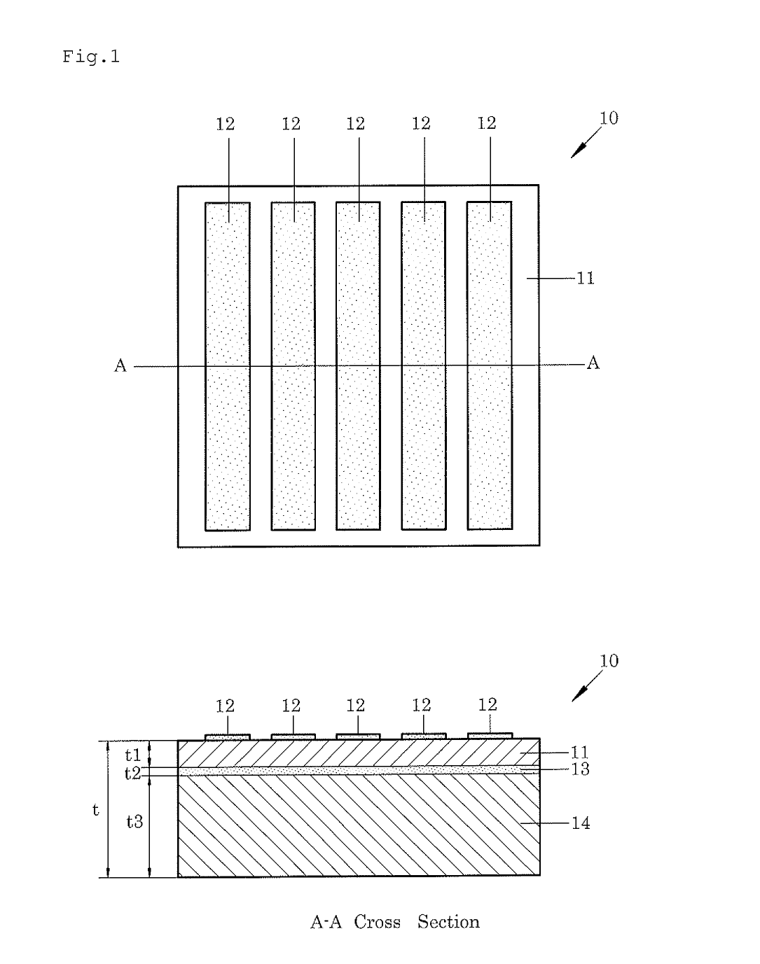

The preferred embodiments of the present invention will now be described with reference to FIG. 1. Identical elements in the FIGURE are designated with the same reference numerals.

### [Transparent Conductive Film]

As shown in FIG. 1, a transparent conductive film 10 of the present invention comprises: a transparent first film 11; a plurality of transparent electrode patterns 12; and a transparent adhesive layer 13; and a transparent second film 14. The first film 11 has a thickness t1 of 15 μm to 55 μm. The plurality of transparent electrode patterns 12 are formed on one surface (the top surface in FIG. 1) of the first film 11. The transparent adhesive layer 13 is laminated on the other surface (the bottom surface in FIG. 1) of the first film 11. The second film 14 is laminated on a surface (the bottom surface in FIG. 1) of the transparent adhesive layer 13 that is on the opposite side of the first film 11. The second film 14 has a thickness t3 1.5 to 6 times as great as the thickness t1 of the first film 11. The transparent adhesive layer 13 is a curing adhesive layer and has a thickness t2 of not less than 0.01 μm and less than 10 μm.

In the transparent conductive film 10 of the present invention, the first film 11 and the second film 14 are laminated with the transparent adhesive layer 13 interposed therebetween. The transparent adhesive layer 13 is composed of a curing adhesive layer having a small thickness of not less than 0.01 μm and less than 10 μm. That is, in the transparent conductive film 10 of the present invention, rigidity of the thin first film 11 is reinforced by the thick second film 14 with the rigid and thin transparent adhesive layer 13 interposed therebetween. The thick second film 14 has less waviness because of high shrinkage resistance. This structure of the transparent conductive film 10 makes it possible to control the generation of waviness.

The transparent adhesive layer 13 to be used for the transparent conductive film 10 of the present invention is composed of a curing adhesive layer with a small thickness of not less than 0.01 μm and less than 10 μm. Thus, the transparent adhesive layer 13 does not have such a cushion characteristic as a pressure-sensitive adhesive layer with a thickness of about 20 μm of a conventional transparent conductive film. However, unlike a resistive touch panel, a capacitance-type touch panel does not need to deform the transparent conductive film when inputted. As a result, the transparent adhesive layer 13 does not need cushion effects. Accordingly, the transparent conductive film 10 of the present invention is suitable for a capacitance-type touch panel.

A pressure-sensitive adhesive layer having a high dielectric constant and a thickness of about 20 μm has been used for a conventional transparent conductive film. In the transparent conductive film 10 of the present invention, the transparent adhesive layer 13 composed of a curing adhesive layer having a low dielectric constant and a thickness of 0.01 μm or more and less than 10 μm is used instead of a pressure-sensitive adhesive layer having a high dielectric constant. This raises the percentage of volume that the first film 11 and the second film 14 account for in the entire transparent conductive film 10. Since the first film 11 and the second film 14 respectively have a dielectric constant lower than a pressure-sensitive adhesive layer and a curing adhesive layer, the transparent conductive film 10 of the present invention has a dielectric constant lower than the conventional transparent conductive film. Accordingly, in the case where the transparent conductive film 10 of the present invention is used for a capacitance-type touch panel, the touch sensitivity becomes higher than the conventional transparent conductive film.

A thickness t of the transparent conductive film 10 of the present invention is the sum of a thickness t1 of the first film 11, a thickness t2 of the transparent adhesive layer 13, and a thickness t3 of the second film 14 (t=t1+t2+t3). The thickness t of the transparent conductive film 10 of the present invention is preferably 60 μm to 250 μm, more preferably 90 μm to 200 μm.

### [First Film]

The first film 11 of the transparent conductive film 10 of the present invention supports the transparent electrode patterns 12. The first film 11 preferably has a thickness of 15 μm to 55 μm, more preferably 20 μm to 40 μm. When the first film 11 has a thickness of less than 15 μm, there are fears that the first film 11 may be difficult to be dealt with due to poor strength thereof. When the thickness of the first film 11 is over 55 μm, there is a possibility that the surface resistance value of the transparent electrode patterns 12 may become higher by the generation of a large amount of volatile components when heated at the time of sputtering or the like. The first film 11 to be used in the present invention has few volatile components because of being thin. This makes it possible to stably obtain the transparent electrode patterns 12 having a small surface resistance value.

A material having superior transparency and heat resistance is preferably used as a material for forming the first film 11. Examples of the material for forming the first film 11 typically include polyethylene terephthalate, polycycloolefin or polycarbonate. The first film 11 may include an easily adhering layer not shown and an index matching layer for adjusting reflectivity not shown formed on one surface or both surfaces thereof. Alternatively, the first film 11 may include a hard coating layer not shown to provide scratch resistance. The easily adhering layer is typically composed of a silane-based coupling agent, a titanate-based coupling agent or an aluminate coupling agent. The index matching layer is typically composed of titanium oxide, zirconium oxide, silicon oxide or magnesium fluoride. The hard coating layer is typically composed of a melamine-based resin, an urethane-based resin, an alkyd-based resin, an acrylic-based resin or a silicone-based resin.

### [Transparent Electrode Pattern]

When the transparent conductive film 10 of the present invention is used for a capacitance-type touch panel, the transparent electrode patterns 12 are used as sensors for detecting the position of a touch. The transparent electrode patterns 12 are usually electrically connected to wirings (not shown) arranged in the periphery of the first film 11 and the wirings are connected to a controller IC (not shown). The shape of the transparent electrode patterns 12 is in any shape such as stripe-shaped as shown in FIG. 1 or diamond-shaped not shown.

The thickness of the transparent electrode patterns 12 is preferably 10 nm to 100 nm, more preferably 10 nm to 50 nm. The transparent electrode patterns 12 are respectively formed typically by a transparent conductor. The transparent conductor means a material which has a high transmittance (not less than 80%) in a visible light region (380 nm to 780 nm) and a surface resistance value per unit area (unit: Ω per square) not more than 500Ω per square. A transparent conductor is formed, for example, from indium tin oxide (ITO), indium zinc oxide, or indium oxide-zinc composite oxide. After a transparent conductor layer is formed on the first film 11, for example, by a sputtering method or a vacuum evaporation method, a photoresist in a desired pattern can be formed on a surface of the transparent conductor layer, and immersed in hydrochloric acid to remove the unnecessary part of the transparent conductor layer to obtain the transparent electrode patterns 12.

### [Transparent Adhesive Layer]

The transparent adhesive layer 13 of the transparent conductive film 10 of the present invention is laminated on a surface of the first film 11 without transparent electrode patterns 12. In other words, the transparent adhesive layer 13 is sandwiched between the first film 11 and the second film 14. The transparent adhesive layer 13 is a curing adhesive layer with a thickness of not less than 0.01 μm and less than 10 μm. The curing adhesive layer is preferably an ultraviolet curing adhesive layer or an electron beam curing adhesive layer in view of the point that curing is possible at a temperature which has no negative effect. Typical examples of the curing adhesive include a base-resin, reactive diluents, and a photopolymerization initiator. The base-resin is a resin in which an acrylic group or an epoxy group is added to both terminals of a polymer chain. The reactive diluents are subject to a cross-linking reaction with the base-resin while reducing the viscosity of the adhesive. The reactive diluents are caused to promote the cross-linking reaction. It is not preferable to use a pressure-sensitive adhesive layer for the transparent adhesive layer 13. Since a pressure-sensitive adhesive layer generally has a great thickness and is soft, it is difficult to completely fix the first film 11 and the second film 14. As a result, there tends to be a gap between the first film 11 and the second film 14 and therefore, it is difficult to prevent waviness of the first film 11 from being generated by protecting the first film 11 with the second film 14.

The transparent adhesive layer 13 composed of a curing adhesive layer has a thickness of not less than 0.01 μm and less than 10 μm, preferably 0.01 μm to 8 μm. In the case where the transparent adhesive layer 13 has a thickness of less than 0.01 μm, there is a possibility of the transparent adhesive layer 13 having insufficient adhesion. And in the case where the transparent adhesive layer 13 has a thickness of over 10 μm, there are fears that curing time may become extremely longer. Alternatively, there are fears that the waviness of the transparent conductive film 10 may become larger because the deformation of the transparent adhesive layer 13 is too severe to be ignored.

### [Second Film]

The second film 14 of the transparent conductive film 10 of the present invention is laminated on the opposite side of the first film 11 of the transparent adhesive layer 13. The thickness t3 of the second film 14 is 1.5 times to 6 times as great as the thickness t1 of the first film 11, preferably 2 times to 6 times, more preferably 3 times to 5 times. In the case where the thickness t3 of the second film 14 is less than 1.5 times as great as the thickness t1 of the first film 11, the transparent conductive film 10 becomes short in shrinkage resistance, which may result in difficulty in control of the generation of waviness. In the case where the thickness t3 of the second film 14 exceeds 6 times of the thickness t1 of the first film 11, there is a possibility of the transparency degree of the transparent conductive film 10 dropping because the thickness t of the transparent conductive film 10 becomes too great. Alternatively, the thickness t of the transparent conductive film 10 becomes too great. There are fears that this may make mounting to a touch panel or the like difficult. In view of the thickness t1 of the first film 11 and the aforementioned magnification, the thickness t3 of the second film 14 is preferably 30 μm to 200 μm, more preferably 45 μm to 150 μm. It is possible to improve shrinkage resistance to reduce the waviness of the first film 11 by setting the thickness t3 of the second film 14 within the above range. In addition, when the transparent conductive film 10 of the present invention is used as an upper electrode of a capacitance-type touch panel and a lower electrode not shown is laminated on a lower surface of the transparent conductive film 10, it is possible to appropriately widen the distance between electrodes so that touch sensitivity can be good.

A material having superior transparency and heat resistance is preferably used as a material for forming the second film 14. Typical examples of the material for forming the second film 14 include polyethylene terephthalate, polycycloolefin or polycarbonate. The second film 14 may include an easily adhering layer not shown and a hard coating layer for providing scratch resistance not shown formed on one surface or both surfaces thereof. Each material for the easily adhering layer of the second film 14 and the hard coating layer is similar to each material for the easily adhering layer and the hard coating layer in the first film 11.

### [Manufacturing Method]

One example of a method for manufacturing a transparent conductive film 10 of the present invention will now be described. Firstly, a transparent conductor layer is formed on one side of the first film 11 with a thickness of 15 μm to 55 μm by a sputtering method. Secondly, an ultraviolet curing adhesive is applied in a thickness of not less than 0.01 μm and less than 10 μm on a surface opposite to the transparent conductor layer to bond the second film 14. The thickness of the second film 14 is 1.5 times to 6 times as great as the first film 11. Thirdly, ultraviolet rays are irradiated from the side of the second film 14 to cure the ultraviolet curing adhesive. Fourthly, a photoresist in a desired pattern is formed on a surface of the transparent conductor layer. Finally, the transparent conductor layer is immersed in hydrochloric acid and the unnecessary transparent conductor layer is removed to obtain desired transparent electrode patterns 12.

According to the manufacturing method of the transparent conductive film 10 of the present invention, only the first film 11 having a small thickness is used as a base when the transparent conductor layer is formed, so that the amount of volatile components generated from the base is little. This reduces the surface resistance value of the transparent conductor layer. In addition, when the transparent electrode patterns 12 are formed, shrinkage resistance increases because the second film 14 having a great thickness is laminated, resulting in control of the generation of waviness of the transparent conductive film 10.

### EXAMPLES

### Example 1

Using a sputtering apparatus having a sintered target of indium-tin oxide containing 97% by weight of indium oxide and 3% by weight of tin oxide, an indium tin oxide (ITO) layer was formed on one surface of a polyethylene terephthalate film (the first film). The thickness of polyethylene terephthalete film was 25 μm and the thickness of the indium tin oxide layer was 22 nm.

Subsequently, an ultraviolet curing-type adhesive was applied on a surface located on the opposite side of the indium tin oxide layer of the polyethylene terephthalate film to bond the first film 11 to the polyethylene terephthalate film (the second film). The ultraviolet curing-type adhesive was DA-141 manufactured by Nagase ChemteX Corporation and had a thickness of 5 μm. The polyethylene terephthalate film (the second film) had a thickness of 100 μm. And then ultraviolet rays (wavelength: 365 nm) were irradiated using a high-pressure mercury lamp from the side of the second film to cure the ultraviolet curing-type adhesive. After that, a photoresist in a desired pattern was formed on a surface of the transparent conductor layer. And then the transparent conductor layer was immersed in hydrochloric acid to remove the unnecessary transparent conductor layer. Subsequently, stripe-shaped transparent electrode patterns were obtained by drying at 140° C. for 30 minutes. As shown in Table 1, a portion with transparent electrode patterns and a portion without transparent electrode patterns in the obtained transparent conductive film had waviness of 0.1 μm.

### Example 2

A transparent conductive film was produced in the same manner as in Example 1 except that the thickness of the second film was 75 μm. As shown in Table 1, a portion with transparent electrode patterns and a portion without transparent electrode patterns in the obtained transparent conductive film had waviness of 0.6 μm.

### Comparative Example 1

A transparent conductive film was produced in the same manner as in Example 1 except that the thickness of the second film was 25 μm. As shown in Table 1, a portion with transparent electrode patterns and a portion without transparent electrode patterns in the obtained transparent conductive film had waviness of 1.5 μm.

TABLE 1

| | | | | Waviness |
|---|---|---|---|---|
| | dl (μm) | d2 (μm) | d2/d1 | (μm) |
| Example 1 | 25 | 100 | 4 | 0.1 |
| Example 2 | 25 | 75 | 3 | 0.6 |
| Comparative Example 1 | 25 | 25 | 1 | 1.5 |

d1: Thickness of a first film
d2: Thickness of a second film
Waviness: Difference of elevation between a portion with transparent electrode patterns and a portion without transparent electrode patterns

### [Measuring Method]

### [Film Thickness]

The thickness of the first film and the second film was measured using a thickness meter (manufactured by OZaki Mfg. Co., Ltd.; Product name: Peacock Digital dial gauge DG-205).

### [Waviness]

The waviness of the transparent conductive film was measured using an Optical Profilometer (manufactured by Veeco Instruments Ltd.; Product name: NT3300).

### INDUSTRIAL APPLICABILITY

While the usage of the transparent conductive film is not particularly limited, the transparent conductive film of the present invention is preferably used for a capacitance-type touch panel, more specifically, a projection capacitance-type touch panel.

This application claims priority from Japanese Patent Application No. 2011-237081, which is incorporated herein by reference.

There has thus been shown and described a novel transparent conductive film which fulfills all the objects and advantages sought therefor. Many changes, modifications, variations and other uses and applications of the subject invention will, however, become apparent to those skilled in the art after considering this specification and the accompanying drawings which disclose the preferred embodiments thereof. All such changes, modifications, variations and other uses and applications which do not depart from the spirit and scope of the invention are deemed to be covered by the invention, which is to be limited only by the claims which follow.

What is claimed is:

1. A transparent conductive film, comprising:
a first transparent film;
a plurality of transparent electrode patterns formed on one surface of the first transparent film;
a transparent adhesive layer laminated on the other surface of the first transparent film; and
a second transparent film laminated on a surface of the transparent adhesive layer that is on the opposite side of the first transparent film, the transparent adhesive layer is a curing adhesive layer, and the second transparent film has a thickness 1.5 times to 6 times as great as the first transparent film has.

2. The transparent conductive film according to claim 1, wherein the first transparent film has a thickness of 15 μm to 55 μm.

3. The transparent conductive film according to claim 1, wherein the transparent adhesive layer has a thickness of not less than 0.01 μm and less than 10 μm.

4. The transparent conductive film according to claim 1, wherein a curing adhesive for forming the curing adhesive layer is an ultraviolet curing adhesive or an electron beam curing adhesive.

5. The transparent conductive film according to claim 1, wherein the first transparent film and the second transparent film respectively have a dielectric constant of 2.0 to 3.5 at 1 MHz.

6. The transparent conductive film according to claim 1, wherein each material for forming the first transparent film and the second transparent film is any one of polyethylene terephthalate, polycycloolefin or polycarbonate.

7. The transparent conductive film according to claim 1, wherein a material for forming the plurality of transparent electrode patterns is any one of indium tin oxide (ITO), indium zinc oxide or indium oxide-zinc composite oxide.
